(19) United States
(12) Patent Application Publication
(10) Pub. No.: US 2005/0029655 A1
(43) Pub. Date: Feb. 10, 2005

(54) Semiconductor device

(75) Inventor: Qiang Wu, Hyogo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.,

(21) Appl. No.: 10/909,368

(22) Filed: Aug. 3, 2004

(30) Foreign Application Priority Data
Aug. 8, 2003 (JP) 2003-290193

(51) Int. Cl. H01L 23/48

(52) U.S. Cl. 257/734

(57) ABSTRACT

To provide a semiconductor device easy to manufacture at low cost and improved in heat dissipation characteristics, the semiconductor device includes a package substrate having a solder bump, a semiconductor chip connected facedown to the package substrate with a terminal of the semiconductor chip connected to the solder bump on the package substrate, a heat spreader located on the semiconductor chip and having a size greater than that of the semiconductor chip when seen from above, and a heat-dispersing adhesive layer interposed between the semiconductor chip and the heat spreader for adhesion thereof. The semiconductor device is unprovided with a support member surrounding the semiconductor chip between the heat spreader and the package substrate for supporting the heat spreader above the package substrate.

### BACKGROUND OF THE INVENTION

1. Field of the Invention

The present invention relates to semiconductors and manufacturing methods thereof, and more particularly to a semiconductor device provided with a package structure having favorable heat dispersion characteristics.

2. Description of the Background Art

In an integrated circuit (IC) package such as a flip chip-ball grid array (FC-BGA), normally, a semiconductor chip mounted facedown on a package substrate has its back surface provided with a tabular heat radiating plate (heat spreader), with a heat-dispersing resin layer interposed therebetween. The heat generated at the semiconductor chip is dispersed through the heat dispersion path of semiconductor chip/heat-dispersing resin layer/heat radiating plate.

The heat radiating plate extends to cover the semiconductor chip like an umbrella. To support the periphery of the umbrella, a ring member is secured to the package substrate by means of a heat-dispersing tape. The ring member is arranged to surround the semiconductor chip. The upper surface of the ring member is adhered to the peripheral portion of the umbrella by means of a heat-dispersing tape, to support the heat radiating plate above the package substrate. The ring member also serves to dissipate the heat generated at the semiconductor chip.

The conventional FC-BGA structure as described above, however, poses the following problems.

(1) The number of members used, and hence, the number of process steps is large, which increases the manufacturing cost from both aspects of member and process.

(2) Chip separation occurs due to the restraint on the package substrate by the ring member.

(3) The power applicable to the semiconductor chip is restricted, due to insufficient heat dissipation capability. In the conventional structure described above, when the heat-dispersing resin layer in the heat dispersion path of semiconductor chip/heat-dispersing resin layer/heat radiating plate has a thickness of 0.1 mm, the internal thermal resistance Θ_{Jc} of the package, as an index of heat dissipation capability, is 0.276° C./W.

To improve the heat dissipation capability, a heat sink may be further provided on the heat radiating plate with a heat-dispersing resin interposed therebetween. In this case, however, two layers of heat-dispersing resin are provided, as in the order of semiconductor chip/heat-dispersing resin (of about 0.1 mm thick)/heat radiating plate/heat-dispersing resin/heat sink, which will not necessarily result in sufficient improvement of the heat dissipation capability.

(4) The heat radiating plate may be separated due to excessive thickness of the heat-dispersing resin and due to the high temperature process following adhesion of the heat radiating plate, which leads to weakening of the heat dissipating effect. The high temperature process may include the ball-attaching process of the IC package, the reflow process for mounting a chip on a PWB (printed wiring board), and others.

Conventionally, various mounting structures have been proposed to improve the properties of IC packages. For example, Japanese Patent Laying-Open No. 2002-033424 proposes a technique to arrange, on the back surface of a semiconductor chip mounted facedown on a package substrate, a tabular heat radiating plate provided with a peripheral wall, with an epoxy resin as an adhesive agent applied therebetween. The peripheral wall of the heat radiating plate is sized to form a support wall between the package substrate and the heat radiating plate, and thus, it functions as a support member supporting the heat radiating plate above the package substrate.

The above-described publication also discloses a structure in which a heat sink having undergone processing for providing projections and depressions and having a cross section of E shape is provided on a heat diffusing plate, and a support member is arranged between the peripheral portion of the heat sink and the package substrate.

Further, Japanese Patent National Publication No. 9-506214 proposes a method including the steps of securing a table provided with pins on a package substrate and passing the tip ends of the pins through the holes provided to the heat radiating plate, to thereby fix the heat radiating plate to the tip ends of the pins.

Still further, Japanese Patent Laying-Open No. 2002-190560 proposes a configuration where a heat sink subjected to grooving and thus having grooves is adhered onto the heat radiating plate of the conventional structure as described above.

However, there is still a demand for a semiconductor device such as an IC package easy to manufacture at low cost while achieving further miniaturization and ensuring better heat dispersion characteristics.

### SUMMARY OF THE INVENTION

An object of the present invention is to provide a semiconductor device easy to manufacture at low cost and improved in heat dissipation characteristics.

A semiconductor device according to the present invention includes: a package substrate having a solder bump thereon; a semiconductor chip connected facedown to the package substrate, with a terminal of the semiconductor chip connected to the solder bump on the package substrate; a heat dissipation member located on the semiconductor chip and having a size greater than a size of the semiconductor chip when seen from above; and a heat-dispersing adhesive layer interposed between the semiconductor chip and the heat dissipation member for adhesion thereof. The device is unprovided with a support member surrounding the semiconductor chip between the heat dissipation member and the package substrate for supporting the heat dissipation member above the package substrate.

With this configuration, a support member otherwise arranged between the heat dissipation member and the package substrate for supporting the heat dissipation member above the package substrate is unprovided, so that the manufacturing process is facilitated and the manufacturing cost is reduced. As the heat-dispersing adhesive layer, a heat-dispersing tape or a heat-dispersing resin may be employed. The heat-dispersing adhesive layer having high adhesive strength is preferable, although such high adhesive strength is not always required. The same applies to the following explanation.

Another semiconductor device according to the present invention includes: a package substrate having a solder bump thereon; a semiconductor chip connected facedown to the package substrate, with a terminal of the semiconductor chip connected to the solder bump on the package substrate; a heat dissipation member located on the semiconductor chip and having a size greater than a size of the semiconductor chip when seen from above; a heat-dispersing adhesive layer interposed between the semiconductor chip and the heat dissipation member; and a metal column arranged between the heat dissipation member and the package substrate to support the heat dissipation member above the package substrate.

With this configuration, the metal column, e.g., solder column, supports the heat dissipation member. This facilitates the manufacturing process and reduces the manufacturing cost. The metal column or the solder column also ensures firm connection, so that it is possible to use an inexpensive heat-dispersing resin having sufficient heat dissipation capability but not so high adhesive strength as the heat-dispersing adhesive layer. Further, flatness and height of the heat dissipation member can be guaranteed. Still further, the heat is transmitted in greater amount via the solder column, leading to increased heat dissipation capability. As a result, the manufacturing cost can further be reduced.

Yet another semiconductor device according to the present invention includes: a package substrate having a solder bump and a pin-securing bump thereon; a semiconductor chip connected facedown to the package substrate, with a terminal of the semiconductor chip connected to the solder bump on the package substrate; a heat dissipation member located on the semiconductor chip and having a size greater than a size of the semiconductor chip when seen from above; a heat-dispersing adhesive layer interposed between the semiconductor chip and the heat dissipation member; and a metal pin secured to the pin-securing bump on the package substrate. The metal pin is passed through a hole provided at the heat dissipation member to support the heat dissipation member over the package substrate.

Yet another semiconductor device according to the present invention includes: a package substrate having a solder bump thereon; a semiconductor chip connected facedown to the package substrate, with a terminal of the semiconductor chip connected to the solder bump on the package substrate; a heat sink having a concavo-convex shape, located on the semiconductor chip and having a size greater than a size of the semiconductor chip when seen from above; and a ring member arranged between the heat sink and the package substrate to surround the semiconductor chip. A height of the ring member, corresponding to a distance of an upper surface of the ring member from the package substrate, and a height of the semiconductor chip, corresponding to a distance of a back surface of the semiconductor chip from the package substrate, are approximately equal to each other, and heat-dispersing adhesive layers are arranged between the ring member and the heat sink, and between the semiconductor chip and the heat sink.

According to this configuration, with provision of the ring member, the heat sink of concavo-convex shape can be attached directly to the back surface of the semiconductor chip. This considerably improves the heat dissipation capability. Inexpensive heat-dispersing resin having low adhesion strength can be used for the heat-dispersing adhesive layers arranged between the semiconductor chip and the heat sink and between the ring member and the heat sink. This reduces the manufacturing cost. Further, the ring member and the semiconductor chip both support the heat sink, so that the heat sink can be held stably.

A manufacturing method of the semiconductor device for the sake of reference includes: the step of forming a solder bump on a package substrate; the step of forming a metal column for supporting a heat dissipation member on one of the package substrate and the heat dissipation member; the step of mounting a semiconductor chip facedown on the package substrate by connecting a terminal of the semiconductor chip to the solder bump on the package substrate; and the step of connecting the metal column to the other of the package substrate and the heat dissipation member to be supported by the metal column, to thereby form a support structure having the package substrate arranged at one end of the metal column and the heat dissipation member arranged at the other end of the metal column.

With this method, the metal column, e.g., solder column, supports the heat dissipation member. The manufacturing process is facilitated and the manufacturing cost is reduced.

Another manufacturing method of the semiconductor device for another reference includes: the step of forming a solder bump and a pin-securing bump on a package substrate; the step of mounting a semiconductor chip facedown on the package substrate by connecting a terminal of the semiconductor chip to the solder bump on the package substrate; the step of arranging a heat-dispersing adhesive layer and a heat dissipation member provided with a hole successively on the semiconductor chip; and the step of passing a metal pin through the hole of the heat dissipation member and making an end of the metal pin joined to the pin-securing bump on the package substrate.

This method greatly facilitates the manufacture of the semiconductor device.

Yet another manufacturing method of the semiconductor device for further reference includes: the step of forming a solder bump on a package substrate; the step of mounting a semiconductor chip facedown on the package substrate by connecting a terminal of the semiconductor chip to the solder bump on the package substrate; the step of attaching a ring member to the package substrate to surround the semiconductor chip, and making a back surface of the semiconductor chip approximately flush with an upper surface of the ring member; and the step of attaching, at room temperature, a heat sink having a concavo-convex shape on the semiconductor chip and the ring member, with heat-dispersing adhesive layers interposed between the semiconductor chip and the heat sink and between the ring member and the heat sink.

With this method, separation of the heat sink from the semiconductor chip due to a high temperature can be avoided. In the semiconductor device manufactured by this method, the distance from the semiconductor chip to the heat sink is shortened, the heat dissipation capability is improved, and the manufacturing cost is reduced. Further, the height of the upper surface of the ring member is made approximately the same as the height of the back surface of the semiconductor chip so as to support the heat sink. Thus, the heat sink can be held stably.

Accordingly, an IC package easy to manufacture at low cost and improved in heat dissipation capability can be obtained using any of the semiconductor devices according to the present invention.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a semiconductor device (IC package) according to a first embodiment of the present invention.

FIG. 2 is a plan view of the package substrate of the IC package in FIG. 1.

FIGS. 3 and 4 respectively show semiconductor devices (IC packages) according to second and third embodiments of the present invention.

FIG. 5 is a plan view of the package substrate of the IC package in FIG. 4.

FIGS. 6 and 7 respectively show semiconductor devices (IC packages) according to third and fourth embodiments of the present invention.

FIG. 8 is a plan view of the package substrate of the IC package in FIG. 7.

FIG. 9 shows a semiconductor device (IC package) according to a fifth embodiment of the present invention.

FIG. 10 shows the IC package of FIG. 9 before attachment of the heat sink.

### DESCRIPTION OF THE PREFERRED EMBODIMENTS

Hereinafter, embodiments of the present invention will be described with reference to the drawings.

### First Embodiment

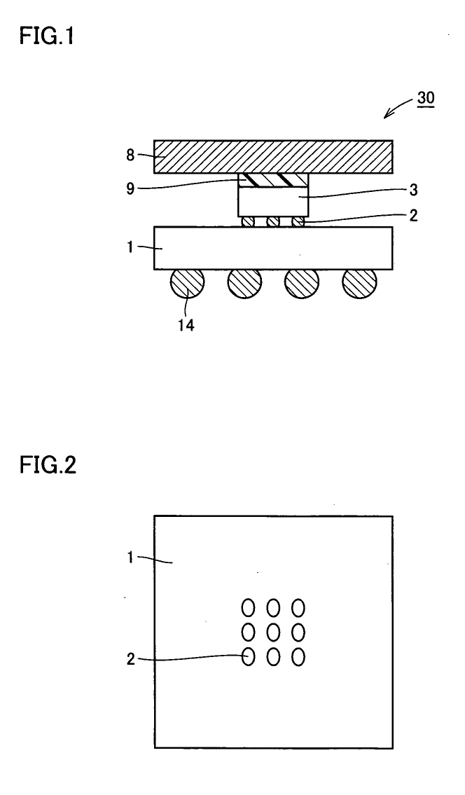

Referring to FIG. 1, the semiconductor device or the IC package 30 according to the first embodiment of the present invention is formed of a semiconductor chip 3 arranged on a package substrate 1, and a heat spreader (heat radiating plate) 8 arranged on semiconductor chip 3. There is no support member provided around the semiconductor chip, between heat spreader 8 and package substrate 1, to support heat spreader 8. Package substrate 1 has solder balls 14 on its lower surface to electrically connect to another part, and solder bumps 2 on its upper surface to conduct to terminals (not shown) of semiconductor chip 3. Semiconductor chip 3 is connected facedown to solder bumps 2. A heat-dispersing adhesive layer 9 is arranged on the back surface of the semiconductor chip to adhere heat spreader 8 to semiconductor chip 3. FIG. 2 is a plan view of package substrate 1. Solder bumps 2 to be connected to terminals (not shown) of semiconductor chip 3 are provided on the upper surface of the rectangular package substrate.

As heat-dispersing adhesive layer 9, a highly adhesive heat-dispersing double-faced tape or a heat-dispersing resin may be employed. The heat-dispersing resin is more preferable in terms of heat dispersion, since resin is generally superior in heat dissipation characteristic to a tape. Using such highly adhesive heat-dispersing adhesive layer 9 can firmly secure heat spreader 8 on the back surface of semiconductor chip 3.

According to the IC package shown in FIG. 1, the conventional ring member is unnecessary. The double-faced adhesive tape that would otherwise be necessary to secure the ring member is unprovided both on the package substrate side and on the heat spreader side. The number of parts, and hence, the number of process steps are considerably decreased, and accordingly, the manufacturing cost can be decreased to about one third compared to the conventional case.

Further, heat spreader 8 is directly adhered to the semiconductor chip, and thus is unaffected by the package substrate. As such, stress acting on the interface between the semiconductor chip and the heat-dispersing adhesive layer is considerably decreased. For example, with the conventional structure provided with the ring member, stress of 12.2 gf/mm² acts on the interface between the semiconductor chip and the heat-dispersing adhesive layer when the distance from the inner periphery of the ring member to the end of the semiconductor chip is 6.2 mm, causing separation of the heat-dispersing adhesive layer from the semiconductor chip. With the configuration shown in FIG. 1, however, the constraint of the package substrate does not work, as described above, and the stress acting on the interface between the semiconductor chip and the heat-dispersing adhesive layer decreases to 1.1 gf/mm². As a result, separation of heat-dispersing adhesive layer 9 from semiconductor chip 3 hardly occurs.

Still further, the heat dispersion characteristics almost the same as conventional can be maintained when the heat spreader having the same surface area as the conventional one, for example, is employed.

### Second Embodiment

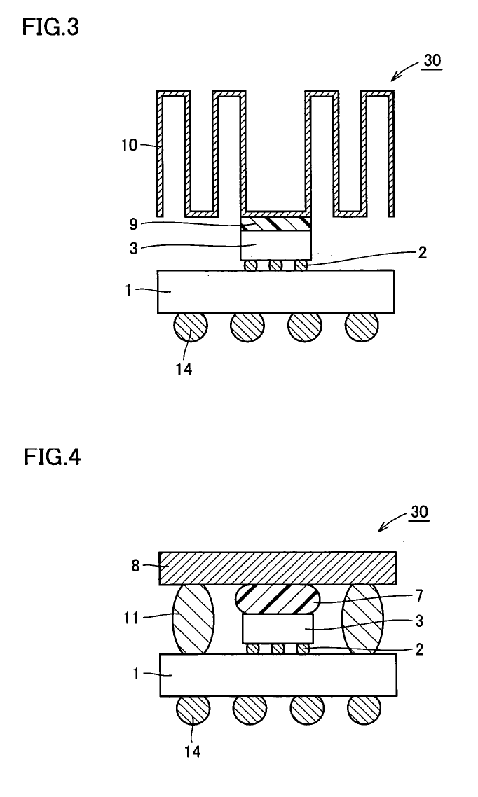

Referring to FIG. 3, the semiconductor device or the IC package 30 according to the second embodiment of the present invention is identical to the IC package shown in FIG. 1, except that heat spreader 8 in the IC package of FIG. 1 as the heat dissipation member is replaced with a heat sink 10 having a cross section of E shape. When such heat sink 10 is employed, the heat dispersion area of the heat dissipation member in the present embodiment is at least doubled compared to the case of using the heat spreader of FIG. 1.

For the heat-dispersing adhesive layer in FIG. 3, a highly adhesive heat-dispersing resin 9 may be employed. Normally, resin is superior in thermal conductivity to a double-faced tape. Thus, using the highly adhesive heat-dispersing resin can further improve the heat dispersion characteristics.

### Third Embodiment

FIG. 4 shows the semiconductor device according to the third embodiment of the present invention, and FIG. 5 shows the package substrate in plan view. The present embodiment is characterized in that discretely arranged solder columns 11 are employed as the support members supporting heat spreader 8. As the heat-dispersing adhesive layer between the back surface of semiconductor chip 3 and heat spreader 8, a heat-dispersing resin 7 not so strong in adhesion may be employed.

Solder columns 11 may be provided in advance to package substrate 1 together with solder bumps 2, as shown in FIG. 5, and semiconductor chip 3 may be mounted facedown. Alternatively, they may be provided in advance to heat spreader 8, instead of package substrate 1.

This configuration guarantees flatness and height of heat spreader 8. As such, heat-dispersing resin 7 not so strong in adhesion but exhibiting favorable heat dispersion characteristics can be employed as the heat-dispersing adhesive layer arranged between the semiconductor chip and the heat dissipation member. Solder columns 11 are connected to both package substrate 1 and heat spreader 8 by means of solder joint. Heat is dispersed from package substrate 1 and heat spreader 8 through the solder, so that the heat dissipation characteristics can be improved. Further, the manufacturing cost is reduced compared to the case of a conventional semiconductor chip mounting structure.

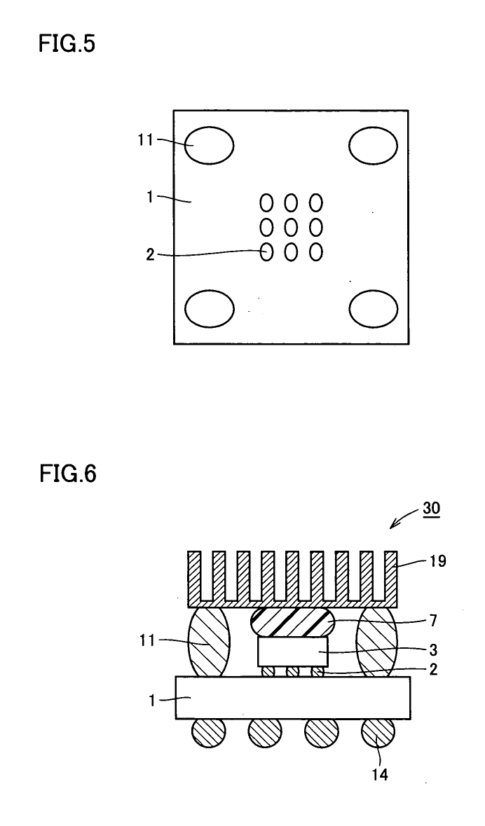

As a modification of FIG. 4, solder columns 11 may be employed to support a heat sink 19, instead of heat spreader 8, over the package substrate, as shown in FIG. 6. Using the heat sink 19 can considerably increase the heat dispersion area, and thus, the heat dissipation characteristics can further be improved. The solder joint can also improve the heat dissipation characteristics, as described above. Herein, heat sink 19 (FIG. 6) subjected to grooving and provided with fins, and heat sink 10 (FIG. 3) having a cross section of E shape are both referred to as a heat sink having a concavo-convex shape.

### Fourth Embodiment

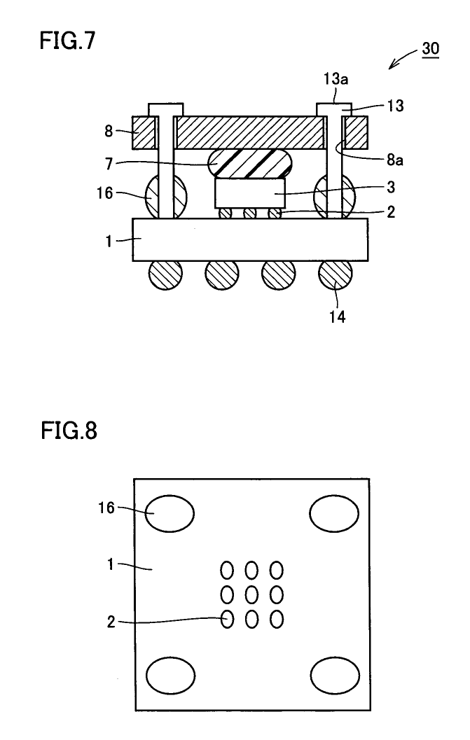

Referring to FIG. 7, the semiconductor device or the IC package 30 according to the fourth embodiment of the present invention is characterized in that metal pins 13 and solder 16 as pin-securing bumps for connecting metal pins 13 to package substrate 1 are employed. Each metal pin having a collar 13a at the top is passed through a hole 8a provided at heat spreader 8. The metal pin has its bottom fixed to solder 16 provided at package substrate 1. In this IC package 30, as the heat-dispersing adhesive layer, a heat-dispersing resin 7 not so strong in adhesion but exhibiting favorable heat dispersion characteristics can be employed.

FIG. 8 shows the package substrate of this IC package 30. As shown in FIG. 8, solder bumps 16 for securing metal pins 13 are provided in advance to the package substrate. When assembling the IC package, semiconductor chip 3 is mounted facedown on package substrate 1 shown in FIG. 8. Next, heat-dispersing resin 7 having good heat dispersion characteristics is arranged on the back surface of semiconductor chip 3, and heat spreader 8 provided with holes 8a is arranged thereon. Thereafter, metal pins 13 are passed holes 8a of heat spreader 8, and the bottom portions of metal pins 13 are connected to solder (pin-securing bumps) 16. The collar 13a located at the upper end of the metal pin exerts the force to press down heat spreader 8 from the top. The contractive force of solder 16 can achieve close contact between heat spreader 8 and heat-dispersing resin 7. To enable the solder joint, it is preferable to process the surface of the metal pin by gold (Au) or solder plating. Solder 16 provided on the package substrate may have a low height of at most 0.2 mm, for example. Although solder bumps 16 are provided at four corners of the package substrate in the present embodiment, the number and places are not so limited. They may be provided . anywhere in any number on the package substrate.

In the above-described structure, the heat spreader is supported by semiconductor chip 3 at the center. Collars 13a of the metal pins also apply downward stress to the heat spreader at the four corners, to keep it in balance.

With such a configuration, the heat spreader and others can be provided very efficiently, and thus, the manufacturing cost can be reduced.

### Fifth Embodiment

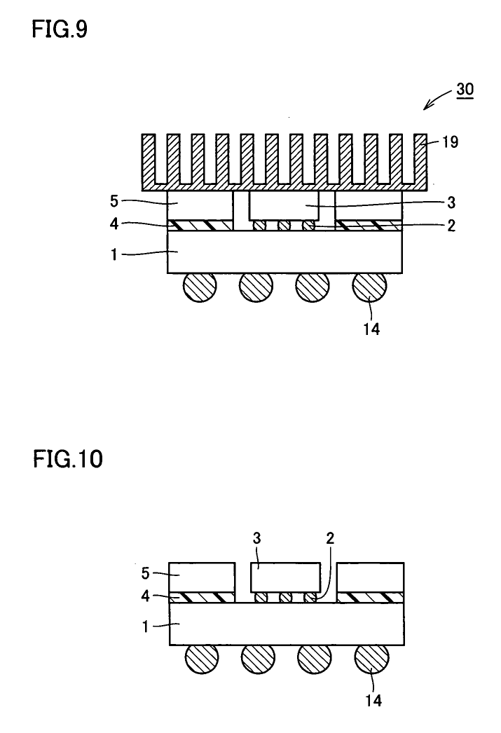

Referring to FIG. 9, the semiconductor device or the IC package 30 according to the fifth embodiment of the present invention is characterized in the following points. A ring member 5 is employed which is arranged to surround the periphery of semiconductor chip 3. The upper surface of the ring member is made flush with the back surface of the semiconductor chip (see FIG. 10), and a very thin (0.2 mm or thinner) heat-dispersing resin or heat-dispersing tape (not shown) is employed for adhesion of the heat sink 19 with the back surface of the semiconductor chip and the upper surface of the ring member. A double-faced adhesive tape 4 is used to fix ring member 5 to package substrate 1.

When the above-described structure is adopted, heat sink 19 is supported by semiconductor chip 3 and ring member 5 the same in height, as shown in FIG. 10. As a result, the heat-dispersing resin as the heat-dispersing adhesive layer can be made extremely thin, and thus, heat sink 19 can be attached at room temperature in the final step. This prevents separation of the heat sink at a high temperature. Further, when Θ_{Jc} is used as the index of heat dissipation capability, compared to the conventional case of Θ_{Jc} of 0.276° C./W, the present embodiment can decrease the Θ_{Jc} to about 0° C./W, for example.

While specific embodiments of the present invention have been described above, embodiments of the present invention will now be explained generally, including repetition of the above description.

In the semiconductor device using metal pins for supporting the heat dissipation member over the package substrate, the metal pins are provided with collars at their tops. The collars of the metal pins protrude from the holes provided at the heat dissipation member and contact the heat dissipation member.

This configuration can further facilitate the manufacturing process. In this structure, the collar of the metal pin exerts the force to press down the heat dissipation member from the top.

Further, in any of the semiconductor devices unprovided with the ring member described above, a tabular heat radiating plate may be employed as the heat dissipation member. This configuration is advantageous in that flatness can readily be guaranteed using the inexpensive member. Further, a heat sink having a concavo-convex shape may be employed as the heat dissipation member. With this configuration, a heat sink having a cross section of E shape, or a metal plate having undergone grooving, for example, can be adhered directly to the back surface of the semiconductor chip, without using the heat radiating plate such as a heat spreader. This can improve heat dissipation capability, while realizing cost reduction with the decreased number of parts.

Although the present invention has been described and illustrated in detail, it is clearly understood that the same is by way of illustration and example only and is not to be taken by way of limitation, the spirit and scope of the present invention being limited only by the terms of the appended claims.

1. A semiconductor device, comprising:
a package substrate having a solder bump thereon;
a semiconductor chip connected facedown to said package substrate, with a terminal of said semiconductor chip connected to the solder bump on said package substrate;
a heat dissipation member located on said semiconductor chip and having a size greater than a size of said semiconductor chip when seen from above; and
a heat-dispersing adhesive layer interposed between said semiconductor chip and said heat dissipation member for adhesion thereof;
the device being unprovided with a support member surrounding said semiconductor chip between said heat dissipation member and said package substrate for supporting said heat dissipation member over said package substrate.

2. The semiconductor device according to claim 1, wherein said heat dissipation member is a tabular heat radiating plate.

3. The semiconductor device according to claim 1, wherein said heat dissipation member is a heat sink having a concavo-convex shape.

4. A semiconductor device, comprising:
a package substrate having a solder bump thereon;
a semiconductor chip connected facedown to said package substrate, with a terminal of said semiconductor chip connected to the solder bump on said package substrate;
a heat dissipation member located on said semiconductor chip and having a size greater than a size of said semiconductor chip when seen from above;
a heat-dispersing adhesive layer interposed between said semiconductor chip and said heat dissipation member; and
a metal column arranged between said heat dissipation member and said package substrate to support said heat dissipation member over said package substrate.

5. The semiconductor device according to claim 4, wherein said heat dissipation member is a tabular heat radiating plate.

6. The semiconductor device according to claim 4, wherein said heat dissipation member is a heat sink having a concavo-convex shape.

7. A semiconductor device, comprising:
a package substrate having a solder bump and a pin-securing bump thereon;
a semiconductor chip connected facedown to said package substrate, with a terminal of said semiconductor chip connected to the solder bump on said package substrate;
a heat dissipation member located on said semiconductor chip and having a size greater than a size of said semiconductor chip when seen from above;
a heat-dispersing adhesive layer interposed between said semiconductor chip and said heat dissipation member; and
a metal pin secured to the pin-securing bump on said package substrate;
said metal pin being passed through a hole provided at said heat dissipation member to support said heat dissipation member over said package substrate.

8. The semiconductor device according to claim 7, wherein said metal pin has a collar on an upper portion that protrudes from the hole of said heat dissipation member and contacts said heat dissipation member.

9. The semiconductor device according to claim 7, wherein said heat dissipation member is a tabular heat radiating plate.

10. The semiconductor device according to claim 7, wherein said heat dissipation member is a heat sink having a concavo-convex shape.

11. A semiconductor device, comprising:
a package substrate having a solder bump thereon;
a semiconductor chip connected facedown to said package substrate, with a terminal of said semiconductor chip connected to the solder bump on said package substrate;
a heat sink having a concavo-convex shape, located on said semiconductor chip and having a size greater than a size of said semiconductor chip when seen from above; and
a ring member arranged between said heat sink and said package substrate to surround said semiconductor chip;
a height of said ring member, corresponding to a distance of an upper surface of said ring member from said package substrate, and a height of said semiconductor chip, corresponding to a distance of a back surface of said semiconductor chip from said package substrate, being approximately equal to each other, and heat-dispersing adhesive layers being arranged between said ring member and said heat sink, and between said semiconductor chip and said heat sink.
